(19) United States
(12) Patent Application Publication
(10) Pub. No.: US 2025/0079377 A1
(43) Pub. Date: Mar. 6, 2025

(54) SEMICONDUCTOR PACKAGE INCLUDING A SEMICONDUCTOR CHIP AND A CONDUCTIVE POST

(71) Applicant: SAMSUNG ELECTRONICS CO., LTD., SUWON-SI (KR)

(72) Inventor: Junghoo Yun, Suwon-si (KR)

(21) Appl. No.: 18/664,590

(22) Filed: May 15, 2024

(30) Foreign Application Priority Data
Sep. 4, 2023 (KR) 10-2023-0117235

(51) Int. Cl. H01L 23/00; H01L 23/498; H01L 25/065

(52) U.S. Cl. CPC H01L 24/16; H01L 23/49816; H01L 23/49822; H01L 24/08; H01L 25/0657; H01L 2224/08146; H01L 2224/08225; H01L 2224/16146; H01L 2224/16225; H01L 2225/06513; H01L 2225/06517; H01L 2924/01029; H01L 2924/1431; H01L 2924/1434; H01L 2924/15311

(57) ABSTRACT

A semiconductor package includes a first substrate, a lower semiconductor chip on the first substrate, a conductive post disposed on the first substrate, and including at least a portion laterally spaced apart from the lower semiconductor chip, an upper semiconductor chip on the lower semiconductor chip and the conductive post, and a plurality of first bumps disposed between the conductive post and the upper semiconductor chip, wherein each of the plurality of first bumps includes a first pillar pattern and a first solder pattern disposed on the first pillar pattern.

### CROSS-REFERENCE TO RELATED APPLICATION

This application is based on and claims priority under 35 U.S.C. § 119 to Korean Patent Application No. 10-2023-0117235, filed on Sep. 4, 2023, in the Korean Intellectual Property Office, the disclosure of which is incorporated by reference herein in its entirety.

### TECHNICAL FIELD

The inventive concept relates to a semiconductor package, and more particularly, to a semiconductor package including a stacked semiconductor chip on a conductive post.

### DESCRIPTION OF RELATED ART

A semiconductor package may encapsulate an integrated circuit chip, making the chip suitable to be used in an electronic product. In forming the semiconductor package, a semiconductor chip may be mounted on a printed circuit board (PCB) and electrically connected to the PCB by using a bonding wire or a bump. Research into increasing the reliability and integration density of semiconductor packages, as well as the miniaturizing the semiconductor packages has been proposed to support the development of the electronics industry.

### SUMMARY

The inventive concept provides a semiconductor package including a semiconductor chip and a conductive post.

According to an aspect of the inventive concept, there is provided a semiconductor package including a first substrate, a lower semiconductor chip on the first substrate, a conductive post disposed on the first substrate and including at least a portion laterally spaced apart from the lower semiconductor chip, an upper semiconductor chip on the lower semiconductor chip and the conductive post, and a plurality of first bumps disposed between the conductive post and the upper semiconductor chip, wherein each of the plurality of first bumps includes a first pillar pattern and a first solder pattern disposed on the first pillar pattern.

According to another aspect of the inventive concept, there is provided a semiconductor package including a redistribution substrate, a first lower semiconductor chip disposed on a top surface of the redistribution substrate, a plurality of conductive posts disposed on the top surface of the redistribution substrate and including at least a portion laterally spaced apart from the first lower semiconductor chip, an upper semiconductor chip disposed on the first lower semiconductor chip and the plurality of conductive posts, and a plurality of solder patterns disposed between a first conductive post of the conductive posts and the upper semiconductor chip, wherein the plurality of solder patterns include a different metal material than the conductive posts, and the first conductive post is configured to supply a voltage to the upper semiconductor chip.

According to a further aspect of the inventive concept, there is provided a semiconductor package including a first redistribution substrate including a first insulating layer, a first seed pattern, and a first redistribution pattern disposed on the first seed pattern, the first insulating layer including a photo-imageable polymer, a solder ball terminal on a bottom surface of the first redistribution substrate, a lower semiconductor chip mounted on a top surface of the first redistribution substrate, the lower semiconductor chip including a lower pad, a through via, and an upper pad, a plurality of conductive posts disposed on the top surface of the first redistribution substrate, and laterally spaced apart from the lower semiconductor chip, an upper semiconductor chip disposed on and connected to the lower semiconductor chip and the conductive posts, a plurality of first bumps disposed between each conductive post of the conductive posts and the upper semiconductor chip, and connected to the conductive posts and the upper semiconductor chip, a plurality of second bumps disposed between the lower semiconductor chip and the upper semiconductor chip, a plurality of lower interconnection structures disposed on the top surface of the first redistribution substrate and laterally spaced apart from the lower semiconductor chip, the upper semiconductor chip, and the conductive posts, a plurality of upper interconnection structures respectively disposed on the lower interconnection structures, a molding layer on the top surface of the first redistribution substrate and covering the lower semiconductor chip, sidewalls of the conductive posts, the upper semiconductor chip, sidewalls of the lower interconnection structures, and sidewalls of the upper interconnection structures, and a second redistribution substrate disposed on the molding layer and the upper interconnection structures and connected to the upper interconnection structures, wherein each of the first bumps includes a first pillar pattern and a first solder pattern disposed between the first pillar pattern and the one conductive post, each of the second bumps includes a second pillar pattern and a second solder pattern disposed between the second pillar pattern and the lower semiconductor chip, and the conductive posts are configured to supply a voltage to the upper semiconductor chip.

### BRIEF DESCRIPTION OF THE DRAWINGS

Embodiments will be more clearly understood from the following detailed description taken in conjunction with the accompanying drawings in which:

FIG. 1A is a diagram illustrating a semiconductor package according to embodiments;

FIG. 1B is a cross-sectional view of the semiconductor package taken along line I-I′ in FIG. 1A;

FIG. 1C is an enlarged view of a region II in FIG. 1A;

FIG. 1D is an enlarged view of a region III in FIG. 1B and a cross-sectional view taken along line IV-IV′ in FIG. 1C;

FIG. 1E illustrates first bumps according to embodiments;

FIG. 2A is a plan view of a semiconductor package according to embodiments;

FIG. 2B is a cross-sectional view of the semiconductor package taken along line I-I′ in FIG. 2A;

FIG. 3 is a diagram illustrating a semiconductor package according to embodiments;

FIG. 4 is a diagram illustrating a semiconductor package according to embodiments;

FIG. 5 is a diagram illustrating a semiconductor package according to embodiments; and

FIGS. 6A, 6B, 6C, 6D, 6E, 6F, 6G, and 6H are diagrams illustrating a method of manufacturing a semiconductor package according to embodiments.

### DETAILED DESCRIPTION

Herein, like reference characters may denote like elements. A semiconductor package and a method of manufacturing the same, according to the inventive concept, are described herein. It should be understood that embodiments of the inventive concept may be implemented singularly or in combination with each other.

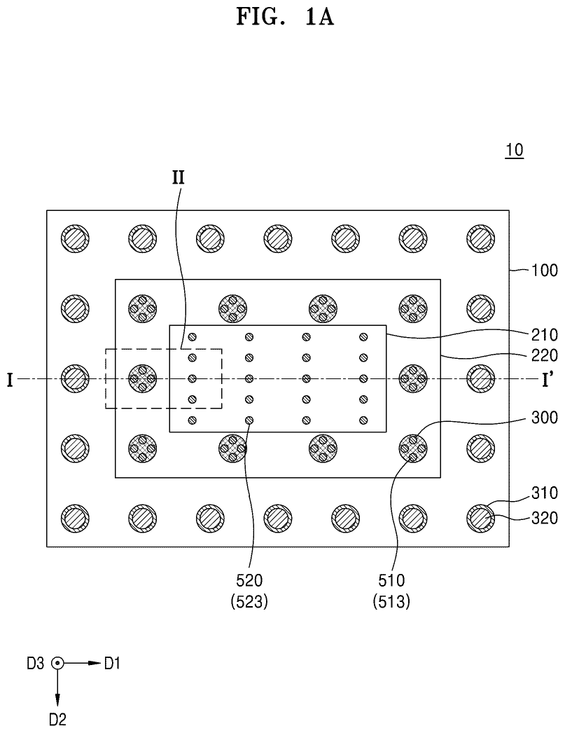

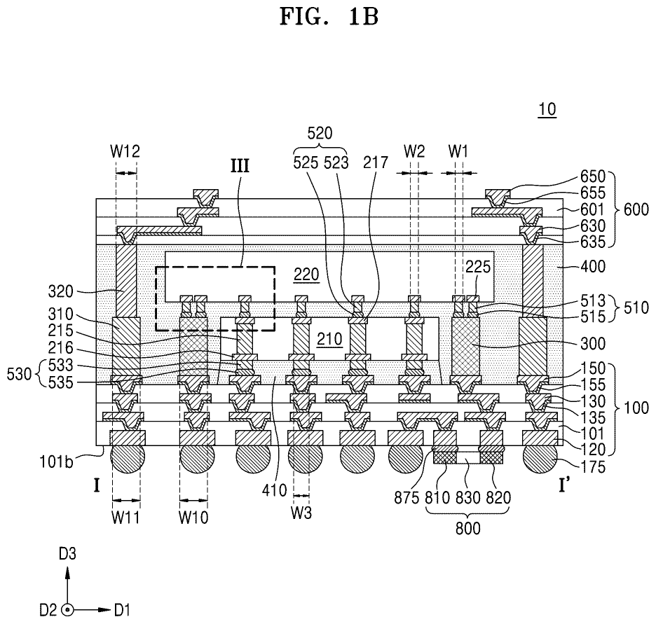

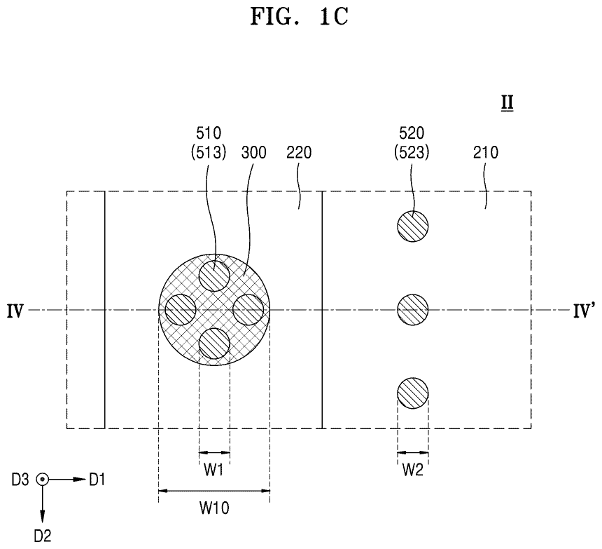

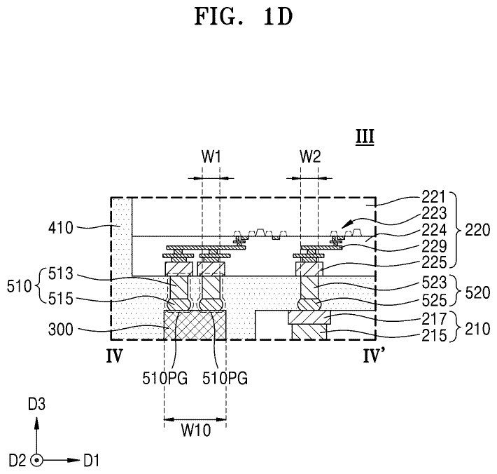

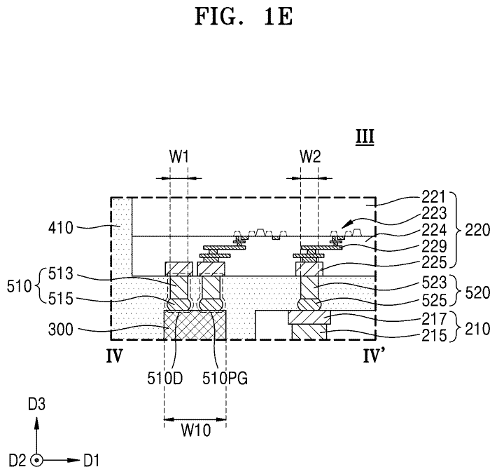

FIG. 1A is a diagram illustrating a semiconductor package according to embodiments.

FIG. 1B is a cross-sectional view of the semiconductor package taken along line I-I′ in FIG. 1A. FIG. 1C is an enlarged view of a region II in FIG. 1A. FIG. 1D is an enlarged view of a region III in FIG. 1B and a cross-sectional view taken along line IV-IV′ in FIG. 1C.

Referring to FIGS. 1A, 1B, 1C, and 1D, a semiconductor package 10 may include a first substrate 100, a plurality of solder ball terminals 175, a lower semiconductor chip 210, an upper semiconductor chip 220, a plurality of conductive posts 300, a plurality of lower bumps 530, a plurality of first bumps 510, a plurality of second bumps 520, a plurality of lower interconnection structures 310, a plurality of upper interconnection structures 320, and a second substrate 600. The semiconductor package 10 may correspond to a lower package.

The first substrate 100 may correspond to, for example, a redistribution substrate. For example, the first substrate 100 may include a printed circuit board (PCB), such as a multi-layer board (MLB) and/or a high-density interconnect (HDI) board. Although the first substrate 100 as a redistribution substrate in FIGS. 1B, 2B, 3, 4, and 5, the inventive concept is not limited thereto. The type and elements of the first substrate 100 may be variously changed.

When the first substrate 100 is a first redistribution substrate, the first substrate 100 may include a plurality of first insulating layers 101, a plurality of under bump patterns 120, a plurality of first redistribution patterns 130, a plurality of first seed patterns 135, a plurality of first seed pads 155, and a plurality of first redistribution pads 150. Being electrically connected to the first substrate 100 may mean being electrically connected to one or more of the first redistribution patterns 130. Electrical connection between elements may include a direct connection therebetween or an indirect connection therebetween through another element.

In the drawings, a first direction D1 may be parallel with a bottom surface 101b of a bottommost first insulating layer 101 among the first insulating layers 101. A second direction D2 may be parallel with the bottom surface 101b of the bottommost first insulating layer 101 and substantially perpendicular to the first direction D1. The first direction D1 and the second direction D2 may form a plane. A third direction D3 may be substantially perpendicular to the first direction D1 and the second direction D2, and to the plane formed by the first direction D1 and the second direction D2. The third direction D3 may be disposed in a vertical direction. The first insulating layers 101, the under bump patterns 120, the first redistribution patterns 130, the first seed patterns 135, the first seed pads 155, and the first redistribution pads 150 are described in detail herein.

The first substrate 100 may include an edge region and a center region. According to a plan view, the edge region of the first substrate 100 may be disposed between the center region of the first substrate 100 and sidewalls of the first substrate 100. According to a plan view, the edge region of the first substrate 100 may surround the center region of the first substrate 100.

The solder ball terminals 175 may be disposed on the bottom surface of the first substrate 100. For example, the solder ball terminals 175 may be disposed on bottom surfaces of the under bump patterns 120 and connected to the under bump patterns 120. The solder ball terminals 175 may correspond, one-to-one, to the under bump patterns 120. The solder ball terminals 175 may be electrically connected to the first redistribution patterns 130 through the under bump patterns 120. For example, a solder ball terminal of the solder ball terminals 175 may be electrically connected to a stack of the first redistribution patterns 130. The solder ball terminals 175 may be laterally spaced apart and electrically separated from each other. Two elements that are laterally spaced apart from each other may mean that the two elements are horizontally separated from each other in the first direction D1 and/or the second direction D2. Being “horizontal” may mean being parallel with the bottom surface 101b of the bottommost first insulating layer 101. The solder ball terminals 175 may include a solder material. For example, the solder material may include tin, bismuth, lead, silver, or an alloy thereof. The solder ball terminals 175 may include a signal solder ball, a ground solder ball, or a power solder ball.

The semiconductor package 10 may further include a passive device 800. The passive device 800 may be disposed on the bottom surface of the first substrate 100. The passive device 800 may be laterally spaced apart from the solder ball terminals 175. The bottom surface of the passive device 800 may be disposed at a higher level than the bottom surfaces of the solder ball terminals 175. The level of an element may refer to the vertical level thereof in the third direction D3. For example, the level difference between two elements may be measured in a direction that is parallel with the third direction D3. For example, the bottom surface of the passive device 800 may be disposed at a higher level than the bottommost surfaces of the solder ball terminals 175. Accordingly, when the solder ball terminals 175 of the semiconductor package 10 are coupled to a board (not shown), the passive device 800 may be separated from the board. Accordingly, the semiconductor package 10 may be appropriately mounted on the board.

The passive device 800 may correspond to, for example, a capacitor. The passive device 800 may include a first conductive terminal 810, a second conductive terminal 820, and an insulator 830. The first conductive terminal 810 and the second conductive terminal 820 may respectively correspond to a first electrode and a second electrode. The second conductive terminal 820 may be spaced apart from the first conductive terminal 810. The insulator 830 may be disposed between the first conductive terminal 810 and the second conductive terminal 820. The structure and elements of the passive device 800 are not limited to those described herein and may be variously changed. For example, the passive device 800 may include an integrated stack capacitor (ISC). In this case, a stack structure (not shown) may be disposed in the insulator 830. The stack structure may include a plurality of conductive layers and dielectric layers disposed among the conductive layers. For example, the passive device 800 may include an inductor or a resistor.

Solder connectors 875 may be disposed respectively disposed between the first conductive terminal 810 and a first under bump pattern of the under bump patterns 120, and between the second conductive terminal 820 and a second under bump pattern of the under bump patterns 120. The solder connectors 875 may be connected between the first conductive terminal 810 and the under bump patterns 120, and between the second conductive terminal 820 and the under bump patterns 120. The solder connectors 875 may be spaced apart and electrically separated from each other. The first conductive terminal 810 may be electrically connected to a first solder ball terminal of the solder ball terminals 175 through a first solder connector of the solder connectors 875 and the first substrate 100. The first solder ball terminal of the solder ball terminals 175 may correspond to a ground solder ball terminal or a power solder ball terminal. Accordingly, a voltage may be applied to the first conductive terminal 810. The voltage may correspond to a ground voltage or a power supply voltage. The second conductive terminal 820 may be electrically connected to a first redistribution pad of the first redistribution pads 150 through a second solder connector of the solder connectors 875 and the first substrate 100. Accordingly, an external voltage may be applied to the passive device 800 through the first solder ball terminal of the solder ball terminals 175 and a voltage output from the passive device 800 may be transmitted to the first redistribution pad 150 electrically connected to the passive device 800.

The lower semiconductor chip 210 may be mounted on the first substrate 100. For example, the lower semiconductor chip 210 may include a memory chip, such as a dynamic random access memory (DRAM) chip or a NAND chip. For example, the lower semiconductor chip 210 may include a logic chip or a buffer chip. The lower semiconductor chip 210 may include first integrated circuits (not shown), lower pads 216, through vias 215, and upper pads 217. The first integrated circuits may be disposed in the lower semiconductor chip 210. The lower pads 216 may be disposed at the bottom of the lower semiconductor chip 210 and the upper pads 217 may be disposed at the top of the lower semiconductor chip 210. At least one of the lower pads 216 and the upper pads 217 may correspond to a chip pad. The through vias 215 may be disposed in the lower semiconductor chip 210. The through vias 215 may connect the lower pads 216 to the upper pads 217, respectively. The upper pads 217 may be respectively connected to the lower pads 216 through the through vias 215. The lower pads 216, the upper pads 217, and the through vias 215 may be connected to the first integrated circuits. The lower pads 216, the upper pads 217, and the through vias 215 may include a conductive material such as metal. For example, the lower pads 216, the upper pads 217, and the through vias 215 may include copper, aluminum, tungsten, and/or titanium. The lower semiconductor chip 210 may correspond to, for example, an interposer chip. In this case, the lower semiconductor chip 210 may include the lower pads 216, the upper pads 217, and the through vias 215 but may not include first integrated circuits.

The lower bumps 530 may be disposed between the first substrate 100 and the lower semiconductor chip 210. Each of the lower bumps 530 may be connected to a first redistribution pad of the first redistribution pads 150 and a lower pad of the lower pads 216. Each of the lower bumps 530 may include a lower pillar pattern 533 and a lower solder pattern 535. The lower pillar pattern 533 may be connected to a lower pad of the lower pads 216. The lower pillar pattern 533 may include metal such as copper. The lower solder pattern 535 may be disposed between and connected to the lower pillar pattern 533 and a first redistribution pad of the first redistribution pads 150. The lower solder pattern 535 may include a different metal material than the lower pillar pattern 533. For example, the lower solder pattern 535 may include a solder material.

The semiconductor package 10 may further include a first underfill film 410. The first underfill film 410 may be disposed in a lower gap between the first substrate 100 and the lower semiconductor chip 210. The first underfill film 410 may cover the sidewalls of the lower bumps 530. The first underfill film 410 may include an insulating polymer such as an epoxy polymer.

The conductive posts 300 may be disposed on the first substrate 100. At least a portion of the conductive posts 300 may be laterally spaced apart from the lower semiconductor chip 210. The conductive posts 300 may be laterally spaced apart from the lower semiconductor chip 210. The conductive posts 300 may be disposed between the lower semiconductor chip 210 and the lower interconnection structures 310. As shown in FIG. 1A, according to a plan view, the conductive posts 300 may surround the lower semiconductor chip 210 and may be spaced apart from the lower semiconductor chip 210. The planar arrangement of the conductive posts 300 may be variously changed.

Each of the conductive posts 300 may be disposed on a first redistribution pad of the first redistribution pads 150. Each of the conductive posts 300 may be electrically connected to a solder ball terminal of the solder ball terminals 175 through the first substrate 100. A voltage may be supplied to the conductive posts 300 through the solder ball terminals 175. The voltage may correspond to a power supply voltage or a ground voltage. Accordingly, each of the conductive posts 300 may function as a voltage supply path. For example, the conductive posts 300 may be configured to supply a voltage to the upper semiconductor chip 220.

At least one of the conductive posts 300 may overlap the passive device 800 according to a plan view and may be electrically connected to the passive device 800, but the inventive concept is not limited thereto. For example, at least one of the conductive posts 300 may be adjacent to the passive device 800 according to a plan view and electrically connected to the passive device 800. Accordingly, the length of a voltage supply path between the passive device 800 and the conductive posts 300 may be reduced. Therefore, a voltage may be stably supplied to one of the conductive posts 300.

A width W10 of each of the conductive posts 300 may be about 5 μm to about 400 μm. The width W10 of each of the conductive posts 300 may be greater than the width of each of the through vias 215. In a case where the width W10 of the conductive posts 300 is at least 5 μm, the resistance of the conductive posts 300 may be reduced. Accordingly, a voltage may be stably supplied to the upper semiconductor chip 220 through the conductive posts 300. In a case where the width W10 of the conductive posts 300 is 400 μm or less, a size of the semiconductor package 10 may be reduced. The conductive posts 300 may include a metal material such as copper.

The upper semiconductor chip 220 may be disposed above the conductive posts 300 and the lower semiconductor chip 210. The upper semiconductor chip 220 may be of a different type than the lower semiconductor chip 210. For example, the upper semiconductor chip 220 may correspond to a logic chip. The width of the upper semiconductor chip 220 may be greater than the width of the lower semiconductor chip 210. For example, the upper semiconductor chip 220 may have one or more edge portions, or non-overlapping portions, that extend beyond the lower semiconductor chip 210 in a plan view. These edge portions may provide areas for electrical connection on a bottom surface of the upper semiconductor chip 220 that may by-pass the lower semiconductor chip 210.

During the operation of the semiconductor package 10, the upper semiconductor chip 220 may emit a relatively large amount of heat. For example, heat generated by the upper semiconductor chip 220 per unit time may be greater than heat generated by the lower semiconductor chip 210 per unit time. According to embodiments, in a case where the upper semiconductor chip 220 is disposed above the lower semiconductor chip 210, heat generated by the upper semiconductor chip 220 may be effectively dissipated to the outside through the second substrate 600.

The second bumps 520 may be disposed between the lower semiconductor chip 210 and the upper semiconductor chip 220. Each of the second bumps 520 may be connected to an upper pad of the upper pads 217 and a chip pad of a plurality of chip pads 225. For example, the chip pads 225 of the upper semiconductor chip 220 may include first chip pads and second chip pads. Each of the second chip pads may be connected to a second bump of the second bumps 520. Accordingly, the upper semiconductor chip 220 may be electrically connected to the lower semiconductor chip 210. That an element is electrically connected to a semiconductor chip may mean, for example, that the element is electrically connected to integrated circuits through chip pads of the semiconductor chip.

Each of the second bumps 520 may include a second pillar pattern 523 and a second solder pattern 525. The second pillar pattern 523 may be disposed in contact with a chip pad of the chip pads 225 of the upper semiconductor chip 220. The second pillar pattern 523 may include metal such as copper. The second solder pattern 525 may be disposed between and connected to the second pillar pattern 523 and an upper pad of the upper pads 217. The second solder pattern 525 may include a different metal material than the second pillar pattern 523, the upper pads 217, and the chip pads 225 of the upper semiconductor chip 220. For example, the second solder pattern 525 may include a solder material.

Each of the second bumps 520 may have a second width W2. The second width W2 may be the width of the second pillar pattern 523. The second width W2 may be about 1 μm to about 70 μm. The second width W2 may be less than a width W3 of the lower bumps 530. Even when at least one of the lower semiconductor chip 210 and the upper semiconductor chip 220 is highly integrated, the second width W2 may satisfy the condition(s) described herein, and accordingly, the electrical connection between the lower semiconductor chip 210 and the upper semiconductor chip 220 may be improved. Each of the lower bumps 530 may be disposed on a first redistribution pad of the first redistribution pads 150. In a case where the width W3 of the lower bumps 530 is greater than the second width W2, limitations to the arrangement and size of the first redistribution pads 150 may be reduced.

A plurality of first bumps 510 may be disposed between and connected to a conductive post of the conductive posts 300 and the upper semiconductor chip 220. The first bumps 510 may be laterally spaced apart from each other. The conductive posts 300 and the first bumps 510 may be provided as a voltage supply path of the upper semiconductor chip 220. When elements of the lower semiconductor chip 210 function as a voltage supply path to the upper semiconductor chip 220, the voltage supply path of the upper semiconductor chip 220 may be relatively complex in the lower semiconductor chip 210. Accordingly, there may be voltage loss during the supply of a voltage to the upper semiconductor chip 220. According to embodiments, the conductive posts 300 may function as a voltage supply path to the upper semiconductor chip 220, and therefore, the voltage supply path between the first substrate 100 and the upper semiconductor chip 220 may be simple. Accordingly, voltage loss between the conductive posts 300 and the upper semiconductor chip 220 may decrease.

Through the use of the conductive posts 300, elements for supplying a voltage to the upper semiconductor chip 220 may be reduced or omitted from the lower semiconductor chip 210. For example, a voltage supply via may be omitted from the lower semiconductor chip 210 or the number of voltage supply vias in the lower semiconductor chip 210 may be reduced. Accordingly, signal paths in the lower semiconductor chip 210 may be effectively designed. The through vias 215 and the second bumps 520 may function as a signal path of the upper semiconductor chip 220. The width W10 of the conductive posts 300 may be greater than the width of the through vias 215. Accordingly, the conductive posts 300 may stably supply a voltage to the upper semiconductor chip 220. For example, the width of the conductive posts 300 may be selected for a designed electrical property, e.g., a reduced voltage drop. In another example, the conductor posts 300 may be provide relatively direct connections to the first substrate 100, with a reduced probability of having a defect.

A plurality of first bumps 510 may be disposed on the top surface of each of the conductive posts 300. For example, the first bumps 510 may be disposed between a conductive post of the conductive posts 300 and the upper semiconductor chip 220. The upper semiconductor chip 220 may be electrically connected to a conductive post of the conductive posts 300 through the first bumps 510. The first bumps 510 may transmit a voltage between a conductive post of the conductive posts 300 and the upper semiconductor chip 220 so that the upper semiconductor chip 220 may be stably supplied with the voltage. For simplicity, description is made with respect to a single conductive post 300 herein.

For example, at least a first bump of the first bumps 510 may vertically overlap the passive device 800. Accordingly, the length of a voltage supply path between the passive device 800 and the upper semiconductor chip 220 may be further reduced.

Each of the first bumps 510 may include a first pillar pattern 513 and a first solder pattern 515. The first pillar pattern 513 may be disposed in contact with a chip pad of the chip pads 225. The chip pad 225 corresponding to the first pillar pattern 513 may be a first chip pad. For example, the first pillar pattern 513 may include metal such as copper. The first solder pattern 515 may be disposed between, and connected to the first pillar pattern 513 and the conductive post 300. The first solder pattern 515 may include a different metal material than the conductive post 300, the first pillar pattern 513, the second pillar pattern 523, and the chip pads 225. For example, the first solder pattern 515 may include a solder material.

Stress may occur because of the difference in a coefficient of thermal expansion (CTE) between any of the first substrate 100, the elements of the upper semiconductor chip 220, the conductive post 300, and/or a first molding layer 400. The stress may be caused by chip-package interaction (CPI). The stress may include a mechanical stress or physical stress. The stress may be applied to the upper semiconductor chip 220 through the conductive post 300. According to embodiments, the first solder pattern 515 may be disposed between the conductive post 300 and the first pillar pattern 513. The first solder pattern 515 may be softer than the conductive post 300, the first pillar pattern 513, and the chip pads 225. The first solder pattern 515 may buffer the stress between the conductive post 300 and the first pillar pattern 513. Accordingly, the elements of the upper semiconductor chip 220 may be prevented from being damaged or a probability of damage may be reduced. The durability and reliability of the semiconductor package 10 may be increased.

The first bumps 510 and the second bumps 520 may be manufactured by a single process. For example, the first pillar pattern 513 may include the same metal as the second pillar pattern 523. The first solder pattern 515 may include the same material as the second solder pattern 525. In a case where the first bumps 510 and the second bumps 520 are manufactured by a single process, the manufacture of the upper semiconductor chip 220, and the first bumps 510 and the second bumps 520 may be simplified. It should be understood that while the first bumps 510 and the second bumps 520 may be manufactured by a single process, the inventive concept is not limited thereto, and the first bumps 510 and the second bumps 520 may be manufactured by multiple processes.

In another example, the first pillar pattern 513 may be disposed between, and connected to the first solder pattern 515 and the conductive post 300. That is, the first bumps 510 may be flipped relative to the example illustrated in FIG. 1B. Similarly, the second bumps 520 may be flipped relative to the example illustrated in FIG. 1B, and the second pillar pattern 523 may be disposed between the second solder pattern 525 and connected to and an upper pad of the upper pads 217.

Each of the first bumps 510 may have a first width W1. The first width W1 of the first bump 510 may correspond to the width of the first pillar pattern 513. The first width W1 may be about 1 μm to about 70 μm. The first width W1 may be about 90% to about 110% of the second width W2. In a case where the first width W1 is the same as or similar to the second width W2, the manufacture of the first bumps 510 and the second bumps 520 and the upper semiconductor chip 220 may be further simplified. The first width W1 may be less than the width W3 of the lower bumps 530. In a case where the width W3 of the lower bumps 530 is greater than the first width W1 of the first bump 510, limitations on the arrangement and size of the first redistribution pads 150 may be reduced.

Referring to FIG. 1D together with FIGS. 1B and 1C, the upper semiconductor chip 220 may include a semiconductor die 221, the second integrated circuits 223, the wiring structures 229, the lower insulating layer 224, and the chip pads 225. The second integrated circuits 223 may be disposed on the bottom surface of the semiconductor die 221. For example, the second integrated circuits 223 may include transistors. The second integrated circuits 223 may correspond to logic circuits but are not limited thereto. The lower insulating layer 224 may be disposed on the bottom surface of the semiconductor die 221 and may cover the second integrated circuits 223. The lower insulating layer 224 may have a multi-layer structure. The wiring structures 229 may be disposed in the lower insulating layer 224 and electrically connected to the second integrated circuits 223. The chip pads 225 may be disposed at the bottom of the upper semiconductor chip 220. The bottom surface of the upper semiconductor chip 220 may include the bottom surface of the lower insulating layer 224. The chip pads 225 may be electrically connected to the second integrated circuits 223 through the wiring structures 229.

A plurality of first bumps 510 may include voltage supply bumps 510PG. The voltage supply bumps 510PG may be disposed on a conductive post 300 and connected to the conductive post 300. Each of the voltage supply bumps 510PG may be electrically connected to the second integrated circuits 223 through a chip pad of the chip pads 225 and the wiring structures 229. A voltage applied to the conductive post 300 may be transmitted to the second integrated circuits 223 through the voltage supply bumps 510PG. The same voltage may be applied from the conductive post 300 to the voltage supply bumps 510PG. In other words, a voltage applied to a voltage supply bump of the voltage supply bumps 510PG may be the same as a voltage applied to the other voltage supply bump 510PG. For example, the voltage supply bumps 510PG may correspond to ground bumps, which may supply a ground voltage. For example, the voltage supply bumps 510PG may correspond to power bumps, which may supply a power supply voltage.

According to embodiments, in a case where a conductive post 300 supplies a voltage to the upper semiconductor chip 220 through the plurality of voltage supply bumps 510PG, the voltage may be stably supplied to the upper semiconductor chip 220.

FIG. 1E illustrates the first bumps 510 according to embodiments and is an enlarged view of the region III in FIG. 1B and a cross-sectional view taken along line IV-IV′ in FIG. 1C.

Referring to FIG. 1E, the first bumps 510 may be connected to a conductive post 300. The first bumps 510 may include at least one voltage supply bump 510PG and at least one dummy bump 510D. As described herein, the voltage supply bump 510PG may be electrically connected to the second integrated circuits 223 through a chip pad of the chip pads 225 and the wiring structures 229. The dummy bump 510D may be electrically isolated from the second integrated circuits 223. A voltage applied from the conductive post 300 to the dummy bump 510D may not be transmitted to the second integrated circuits 223. The dummy bump 510D may physically support the upper semiconductor chip 220. Each of the dummy bump 510D and the voltage supply bump 510PG may include a second pillar pattern 523 and a second solder pattern 525. The second pillar pattern 523 and the second solder pattern 525 have been described herein.

Referring again to FIGS. 1A and 1B, interconnection structures may be disposed in the edge region of the top surface of the first substrate 100. The interconnection structures may include the lower interconnection structures 310 and the upper interconnection structures 320. Each of the lower interconnection structures 310 may be disposed on and connected to a first redistribution pad of the first redistribution pads 150. Each of the lower interconnection structures 310 may be electrically connected to the lower semiconductor chip 210 or a solder ball terminal of the solder ball terminals 175 through the first substrate 100.

The lower interconnection structures 310 may be laterally spaced apart from the lower semiconductor chip 210 and the conductive post 300. The lower interconnection structures 310 may be laterally spaced apart from each other. The height of each of the lower interconnection structures 310 may be about 95% to about 105% of the height of the conductive post 300. The lower interconnection structures 310 may include the same metal material as the conductive post 300. For example, the lower interconnection structures 310 may include copper, titanium, and/or an alloy thereof. A width W11 of the lower interconnection structures 310 may be the same as or different from the width W10 of the conductive post 300. Each of the lower interconnection structures 310 may have a cylindrical shape.

The upper interconnection structures 320 may be respectively disposed on the lower interconnection structures 310 and electrically connected to the lower interconnection structures 310. The upper interconnection structures 320 may be laterally spaced apart from the upper semiconductor chip 220. Each of the upper interconnection structures 320 may have a cylindrical shape. The upper interconnection structures 320 may include the same metal material as the lower interconnection structures 310. For example, the upper interconnection structures 320 may include copper. A width W12 of each of the upper interconnection structures 320 may be less than the width W11 of a lower interconnection structure of the lower interconnection structures 310, which is connected to each upper interconnection structure 320. Accordingly, even when a process error occurs during a process of forming the upper interconnection structures 320, the upper interconnection structures 320 may be respectively and appropriately formed on the top surfaces of the lower interconnection structures 310. For example, the bottom surfaces of the upper interconnection structures 320 may not be separated from the top surfaces of the lower interconnection structures 310.

The first molding layer 400 may be formed on the first substrate 100 to cover the lower semiconductor chip 210, the upper semiconductor chip 220, and the conductive post 300. The first molding layer 400 may cover the sidewalls of the lower interconnection structures 310 and the sidewalls of the upper interconnection structures 320. The top surface of the first molding layer 400 may be coplanar with the top surfaces of the upper interconnection structures 320. The first molding layer 400 may further extend into a first gap between the conductive post 300 and the upper semiconductor chip 220 to cover the sidewalls of the first bumps 510. The first molding layer 400 may further extend into a second gap between the lower semiconductor chip 210 and the upper semiconductor chip 220 to cover the sidewalls of the second bumps 520. For example, the first molding layer 400 may include an insulating polymer such as an epoxy molding compound (EMC). The first molding layer 400 may include a different material than the first underfill film 410.

The second substrate 600 may be disposed on the upper semiconductor chip 220, the first molding layer 400, and the upper interconnection structures 320. The second substrate 600 may be electrically connected to the first substrate 100 through the upper interconnection structures 320. The second substrate 600 may correspond to, for example, a second redistribution substrate. The second substrate 600 may include, for example, a PCB, such as an MLB and/or an HDI board. Although it is illustrated in FIGS. 1B, 2B, 3, 4, and 5 that the second substrate 600 is the second redistribution substrate, the inventive concept is not limited thereto. The type and elements of the second substrate 600 may be variously changed.

For example, when the second substrate 600 is the second redistribution substrate, the second substrate 600 may include a second insulating layer 601, second redistribution patterns 630, second seed patterns 635, second seed pads 655, and second redistribution pads 650. Being electrically connected to the second substrate 600 may mean being electrically connected to a first redistribution pattern of the first redistribution patterns 630. The second insulating layer 601, the second redistribution patterns 630, the second seed patterns 635, the second seed pads 655, and the second redistribution pads 650 are described in detail herein.

The second substrate 600 may include a plurality of second insulating layers 601. The second insulating layers 601 may be stacked on the first molding layer 400. The second insulating layers 601 may include a photo-imageable dielectric (PID) material. The PID material may include a polymer. For example, the PID material may include at least one of photosensitive polyimide, polybenzoxazole, phenolic polymer, or benzocyclobutene polymer. For example, the second insulating layers 601 may include the same materials. The interface between adjacent second insulating layers 601 may not be distinct. The number of second insulating layers 601 may be variously changed.

The second redistribution patterns 630 may be disposed in and on the second insulating layers 601. A lower portion of each of the second redistribution patterns 630 may be disposed in a second insulating layer of the second insulating layers 601. The width of an upper portion of each of the second redistribution patterns 630 may be greater than the width of the lower portion of each second redistribution pattern 630. The upper portion of the second redistribution pattern 630 may extend on the top surface of a second insulating layer of the second insulating layers 601. The second redistribution patterns 630 may include metal such as copper.

The second redistribution patterns 630 may include a second lower redistribution pattern and a second upper redistribution pattern, which are stacked on each other. The second lower redistribution pattern may be disposed on and connected to an upper interconnection structure of the upper interconnection structures 320. The second upper redistribution pattern may be disposed on and connected to the second lower redistribution pattern.

Each of the second seed patterns 635 may be disposed on the bottom surface of a second redistribution pattern of the second redistribution patterns 630. The second seed patterns 635 may include a different material than the upper interconnection structures 320 and the second redistribution patterns 630. For example, the second seed patterns 635 may include a conductive seed material. The conductive seed material may include copper, titanium, and/or an alloy thereof. The second seed patterns 635 may function as barrier layers to inhibit or prevent diffusion of a material of the second redistribution patterns 630.

Each of the second redistribution pads 650 may be disposed on and connected to a second redistribution pattern of the second redistribution patterns 630. For example, each of the second redistribution pads 650 may be disposed on the second upper redistribution pattern. The second redistribution pads 650 may be laterally spaced apart from each other. A lower portion of each of the second redistribution pads 650 may be disposed in a topmost second insulating layer 601. An upper portion of each of the second redistribution pads 650 may extend on the top surface of the topmost second insulating layer 601. The second redistribution pads 650 may include, for example, a metal material such as copper.

The second redistribution pads 650 may be respectively connected to the upper interconnection structures 320 through the second redistribution patterns 630. Through the use of the second redistribution patterns 630, at least one second redistribution pad 650 may not be vertically aligned with an upper interconnection structure 320, which is electrically connected to the second redistribution pad 650. Accordingly, the arrangement of the second redistribution pads 650 may be freely designed. The number of second redistribution patterns 630 stacked between an upper interconnection structure of the upper interconnection structures 320 and a second redistribution pad of the second redistribution pads 650 is not limited to that illustrated in the drawings but may be variously changed. For example, one second redistribution pattern 630 or at least three second redistribution patterns 630 may be disposed between an upper interconnection structure of the upper interconnection structures 320 and a second redistribution pad of the second redistribution pads 650.

Each of the second seed pads 655 may be disposed between a topmost second redistribution pattern of topmost second redistribution patterns 630 and a second redistribution pad of the second redistribution pads 650. The second seed pads 655 may include a conductive seed material.

The first substrate 100 according to an embodiment is described in detail herein.

When the first substrate 100 is a redistribution substrate, the first substrate 100 may include the first insulating layers 101, the under bump patterns 120, the first redistribution patterns 130, the first seed patterns 135, the first seed pads 155, and the first redistribution pads 150. For example, the first insulating layers 101 may include an organic material such as a PID material. In an example in which the first insulating layers 101 include the same materials, an interface between adjacent first insulating layers 101 may not be distinct. The number of first insulating layers 101 stacked on each other may be variously changed.

The under bump patterns 120 may be disposed in the bottommost first insulating layer 101. The bottom surfaces of the under bump patterns 120 may not be covered with the bottommost first insulating layer 101. The under bump patterns 120 may respectively function as pads of the solder ball terminals 175. The under bump patterns 120 may be laterally spaced apart from each other and electrically insulated from each other. The under bump patterns 120 may include a metal material such as copper.

The first redistribution patterns 130 may be disposed on the under bump patterns 120 and electrically connected to the under bump patterns 120. The first redistribution patterns 130 may include metal such as copper. A lower portion of each of the first redistribution patterns 130 may be disposed in a first insulating layer of the first insulating layers 101. The width of an upper portion of each of the first redistribution patterns 130 may be greater than the width of the lower portion of each first redistribution pattern 130. The upper portion of each of the first redistribution patterns 130 may extend on the top surface of a first insulating layer of the first insulating layers 101.

The first redistribution patterns 130 may include a first lower redistribution pattern and a first upper redistribution pattern. The first lower redistribution pattern may be disposed on an under bump pattern of the under bump patterns 120. The first upper redistribution pattern may be disposed on and connected to the first lower redistribution pattern.

Each of the first seed patterns 135 may be disposed on the bottom surface of a first redistribution pattern of the first redistribution patterns 130. The first seed patterns 135 may include a different material than the under bump patterns 120 and the first redistribution patterns 130. For example, the first seed patterns 135 may include a conductive seed material. The first seed patterns 135 may function as barrier layers to inhibit or prevent diffusion of a material of the first redistribution patterns 130.

The first redistribution pads 150 may be disposed in a topmost first insulating layer 101 and may extend to the top surface of the topmost first insulating layer 101. A lower portion of each of the first redistribution pads 150 may be disposed in the topmost first insulating layer 101. An upper portion of each of the first redistribution pads 150 may extend on the top surface of the topmost first insulating layer 101. The upper portion of each of the first redistribution pads 150 may be wider than the lower portion thereof and connected to the lower portion thereof. The first redistribution pads 150 may be laterally spaced apart from each other. Each of the first redistribution pads 150 may be disposed on and connected to a first redistribution pattern of the first redistribution patterns 130. At least one of the first redistribution pads 150 may be connected to an under bump pattern of the under bump patterns 120 through the first upper redistribution pattern and the first lower redistribution pattern. Through the use of the first redistribution patterns 130, at least one first redistribution pad 150 may not be vertically aligned with an under bump pattern 120, which may be electrically connected to the first redistribution pad 150. Accordingly, the arrangement of the first redistribution pads 150 may be freely designed. The number of first redistribution patterns 130 stacked between an under bump pattern of the under bump patterns 120 and a first redistribution pad of the first redistribution pads 150 is not limited to that illustrated in the drawings but may be variously changed.

The first seed pads 155 may be respectively disposed on the bottom surfaces of the first redistribution pads 150. Each of the first seed pads 155 may be disposed between the first upper redistribution pattern among the first redistribution patterns 130 and a first redistribution pad of the first redistribution pads 150 and may extend between the topmost first insulating layer 101 and the first redistribution pad 150. The first seed pads 155 may include a different material than the first redistribution pads 150. For example, the first seed pads 155 may include a conductive seed material.

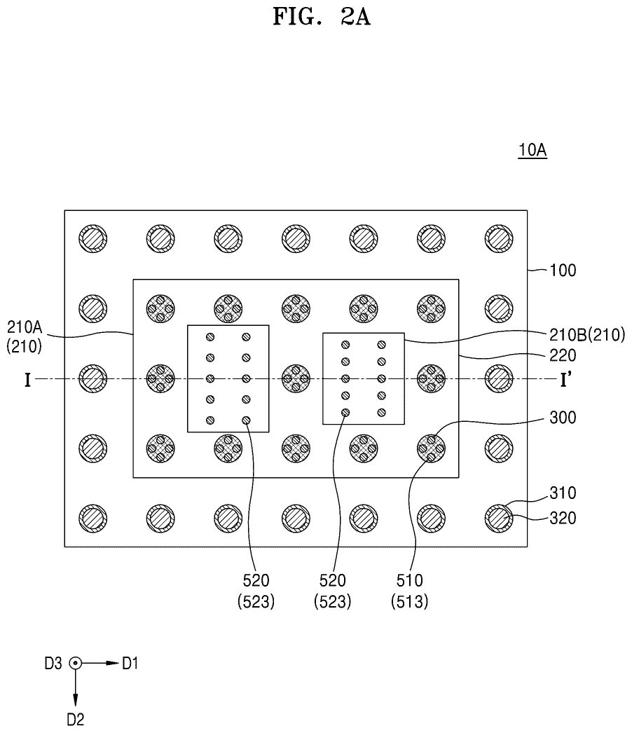

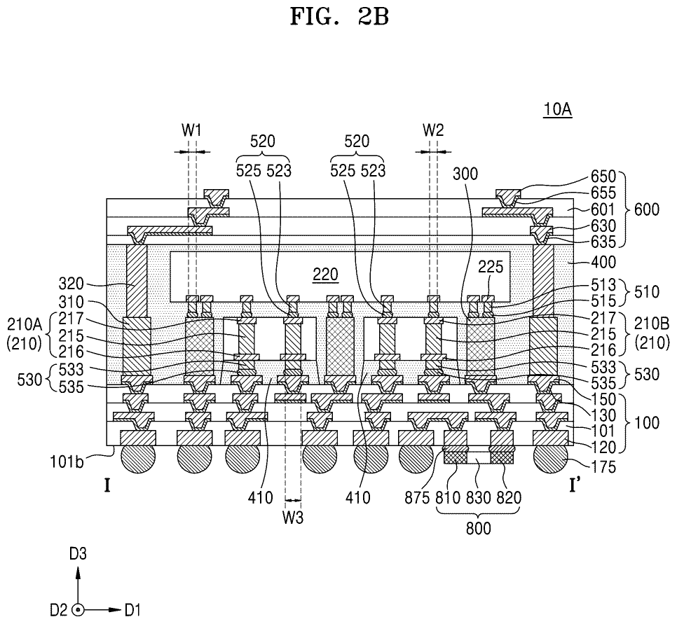

FIG. 2A is a plan view of a semiconductor package according to embodiments. FIG. 2B is a cross-sectional view of the semiconductor package taken along line I-I′ in FIG. 2A. Redundant descriptions may be omitted.

Referring to FIGS. 2A and 2B, a semiconductor package 10A may include the first substrate 100, the solder ball terminals 175, the lower semiconductor chip 210, the upper semiconductor chip 220, the conductive posts 300, the lower bumps 530, the first bumps 510, the second bumps 520, the lower interconnection structures 310, the upper interconnection structures 320, and the second substrate 600. The semiconductor package 10A may correspond to a lower package.

The lower semiconductor chip 210 may include a first lower semiconductor chip 210A and a second lower semiconductor chip 210B. Each of the first lower semiconductor chip 210A and the second lower semiconductor chip 210B may include lower pads 216, through vias 215, and upper pads 217, as described herein with reference to FIG. 1B. The size of the second lower semiconductor chip 210B may be the same as, or different from the size of the first lower semiconductor chip 210A. The first lower semiconductor chip 210A and the second lower semiconductor chip 210B may be the same types of chips as or different types of chips. For example, both the first lower semiconductor chip 210A and the second lower semiconductor chip 210B may be memory chips. Alternatively, one of the first lower semiconductor chip 210A or the second lower semiconductor chip 210B may be a memory chip and the other one may be a buffer chip, a logic chip, or an interposer chip. However, when the first lower semiconductor chip 210A and the upper semiconductor chip 220 are both logic chips, the logic chips may be of different types.

The lower bumps 530 may be disposed between the first substrate 100 and the first lower semiconductor chip 210A and between the first substrate 100 and the second lower semiconductor chip 210B. The first lower semiconductor chip 210A and the second lower semiconductor chip 210B may be connected to the first substrate 100 through the lower bumps 530. First underfill films 410 may be respectively disposed between the first substrate 100 and the first lower semiconductor chip 210A, and between the first substrate 100 and the second lower semiconductor chip 210B.

The conductive posts 300 may be laterally spaced apart from the first lower semiconductor chip 210A and the second lower semiconductor chip 210B. For example, the conductive posts 300 may be disposed between the first lower semiconductor chip 210A and the lower interconnection structures 310, between the second lower semiconductor chip 210B and the lower interconnection structures 310, and between the first lower semiconductor chip 210A and the second lower semiconductor chip 210B.

The upper semiconductor chip 220 may be disposed above the first lower semiconductor chip 210A, the second lower semiconductor chip 210B, and the conductive posts 300.

A plurality of first bumps 510 may be disposed on the top surface of each of the conductive posts 300. The upper semiconductor chip 220 may be electrically connected to a conductive post of the conductive posts 300 through the plurality of first bumps 510. The first width W1 of each of the first bumps 510 may be less than the width W3 of the lower bumps 530.

The second bumps 520 may be disposed between the first lower semiconductor chip 210A and the upper semiconductor chip 220 and between the second lower semiconductor chip 210B and the upper semiconductor chip 220. The upper semiconductor chip 220 may be electrically connected to the first lower semiconductor chip 210A and the second lower semiconductor chip 210B through the second bumps 520. The second width W2 of each of the second bumps 520 may be less than the width W3 of the lower bumps 530. The second width W2 may be about 90% to about 110% of the first width W1.

The number of lower semiconductor chips 210 may be variously changed. For example, the lower semiconductor chip 210 may further include a third lower semiconductor chip.

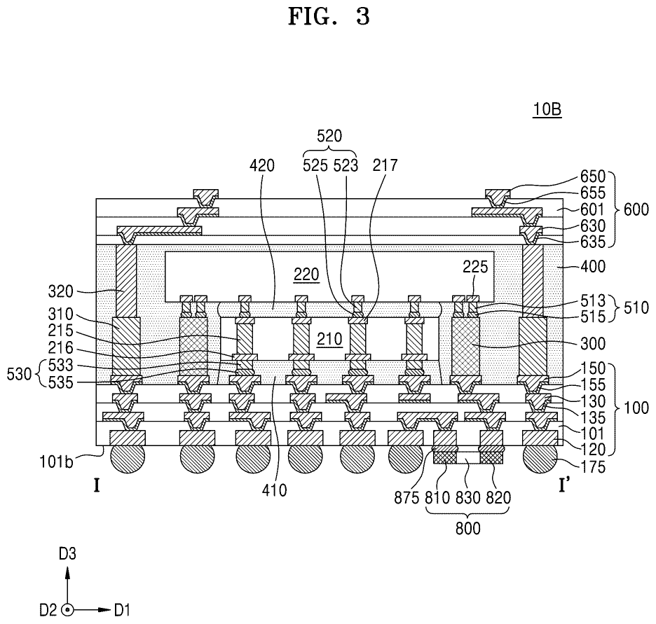

FIG. 3 is a diagram illustrating a semiconductor package according to embodiments and corresponds to a cross-section taken along line I-I′ in FIG. 1A.

Referring to FIG. 3, a semiconductor package 10B may further include a second underfill film 420. That is, the semiconductor package 10B may include the second underfill film 420, the first substrate 100, the solder ball terminals 175, the lower semiconductor chip 210, the upper semiconductor chip 220, the conductive posts 300, the lower bumps 530, the first underfill film 410, the first bumps 510, the second bumps 520, the lower interconnection structures 310, the upper interconnection structures 320, and the second substrate 600.

The second underfill film 420 may be disposed in the second gap between the lower semiconductor chip 210 and the upper semiconductor chip 220. The second underfill film 420 may cover the sidewalls of the second bumps 520. The second underfill film 420 may include an insulating polymer such as an epoxy polymer. The second underfill film 420 may include a different material than the first molding layer 400.

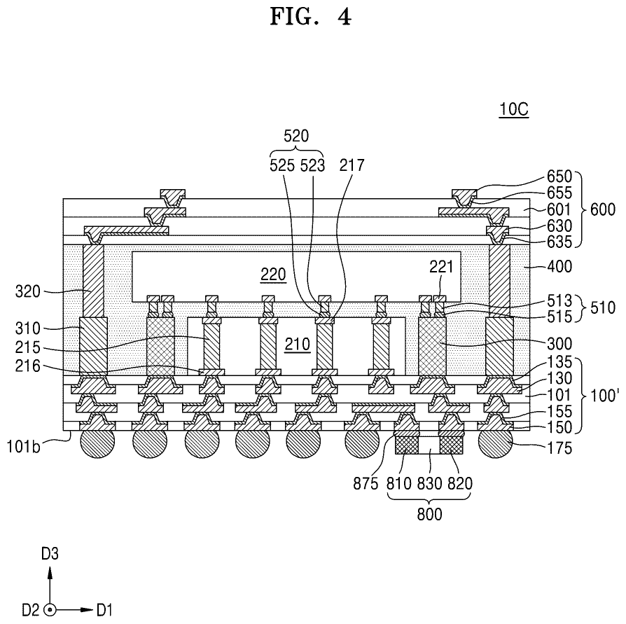

FIG. 4 is a diagram illustrating a semiconductor package according to embodiments and corresponds to a cross-section taken along line I-I′ in FIG. 1A.

Referring to FIG. 4, a semiconductor package 10C may include a first substrate 100′, the solder ball terminals 175, the lower semiconductor chip 210, the upper semiconductor chip 220, the conductive posts 300, the first bumps 510, the second bumps 520, the lower interconnection structures 310, the upper interconnection structures 320, and the second substrate 600. However, the semiconductor package 10C may not include the lower bumps 530 and the first underfill film 410, which have been described herein with reference to FIG. 1B.

The first substrate 100′ may correspond to a redistribution substrate. The first substrate 100′ may include the first insulating layers 101, the first redistribution patterns 130, the first seed patterns 135, the first seed pads 155, and the first redistribution pads 150. However, the first substrate 100′ may not include the under bump patterns 120 described herein with reference to FIG. 1B. The first substrate 100′ may be disposed in direct contact with the lower semiconductor chip 210, the conductive posts 300, the lower interconnection structures 310, and the first molding layer 400. For example, the topmost first insulating layer 101 may be disposed in direct contact with the bottom surface of the lower semiconductor chip 210 and the bottom surface of the first molding layer 400.

The first seed patterns 135 may be respectively disposed on the top surfaces of the first redistribution patterns 130. The first seed patterns 135 in the topmost first insulating layer 101 may be respectively connected to the lower pads 216, the conductive posts 300, and the lower interconnection structures 310.

Each of the first redistribution pads 150 may be disposed in the bottommost first insulating layer 101 and on the bottom surface of the bottommost first redistribution patterns 130. The first seed pads 155 may be respectively disposed on the top surfaces of the first redistribution pads 150. Each of the solder ball terminals 175 may be disposed on the bottom surface of a first redistribution pad of the first redistribution pads 150.

The semiconductor package 10C may be manufactured by a chip-first process but is not limited thereto.

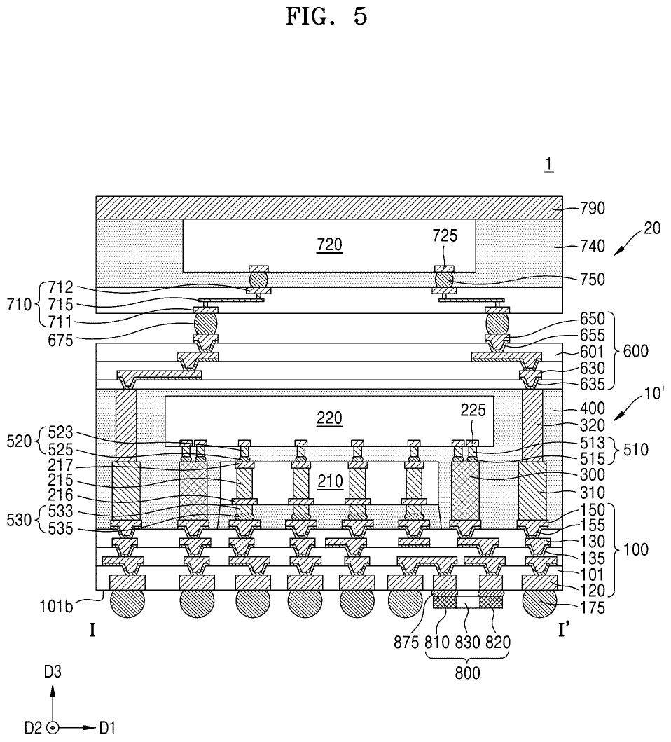

FIG. 5 is a diagram illustrating a semiconductor package according to embodiments and corresponds to a cross-section taken along line I-I′ in FIG. 1A.

A semiconductor package 1 of FIG. 5 may include a lower package 10′ and an upper package 20. The lower package 10′ may be substantially the same as the semiconductor package 10 described with reference to FIGS. 1A to 1C. For example, the lower package 10′ may include the first substrate 100, the solder ball terminals 175, the lower semiconductor chip 210, the upper semiconductor chip 220, the conductive posts 300, the lower bumps 530, the first bumps 510, the second bumps 520, the lower interconnection structures 310, the upper interconnection structures 320, and the second substrate 600. In an example, the lower package 10′ may be substantially the same as the semiconductor package 10A of FIGS. 2A and 2B, the semiconductor package 10B of FIG. 3, or the semiconductor package 10C of FIG. 4.

The upper package 20 may include an upper substrate 710, a memory semiconductor chip 720, and a second molding layer 740. The upper substrate 710 may be disposed above the second substrate 600 and spaced apart from the top surface of the second substrate 600. The upper substrate 710 may correspond to a PCB or a redistribution layer. The upper substrate 710 may include first metal pads 711, second metal pads 712, and metal wiring lines 715. The first metal pads 711 may be disposed at the bottom of the upper substrate 710 and the second metal pads 712 may be disposed at the top of the upper substrate 710. Each of the metal wiring lines 715 may be disposed in the upper substrate 710 and connected to a first metal pad of the first metal pads 711 and a second metal pad of the second metal pads 712.

The semiconductor package 1 may further include connection terminals 675. Each of the connection terminals 675 may be disposed between the second substrate 600 and the upper substrate 710 and connected to a second redistribution pad of the second redistribution pads 650 and a first metal pad of the first metal pads 711. Accordingly, the upper substrate 710 may be electrically connected to the second substrate 600 through the connection terminals 675. The connection terminals 675 may include a solder material. Although not shown, the connection terminals 675 may further include metal pillar patterns.

The memory semiconductor chip 720 may be mounted on the top surface of the upper substrate 710. The upper package 20 may further include conductive bumps 750. Each of the conductive bumps 750 may be disposed between the upper substrate 710 and the memory semiconductor chip 720 and connected to a second metal pad of the second metal pads 712 and a memory chip pad 725 of the memory semiconductor chip 720. The conductive bumps 750 may include a solder material. The upper package 20 may include, for example, a plurality of memory semiconductor chips 720. In an example, the conductive bumps 750 may be omitted, and the memory semiconductor chip 720 may be electrically connected to the upper substrate 710 through a bonding wire (not shown).

The second molding layer 740 may be disposed on the upper substrate 710 and may cover side surfaces of the memory semiconductor chip 720. The second molding layer 740 may expose the top surface of the memory semiconductor chip 720. The second molding layer 740 may also cover the top surface of the memory semiconductor chip 720. The second molding layer 740 may include an insulating polymer such as an EMC.

The upper package 20 may further include a heat dissipation structure 790. The heat dissipation structure 790 may be disposed on the top surface of the memory semiconductor chip 720 and the top surface of the second molding layer 740. The heat dissipation structure 790 may extend to a side surface of the second molding layer 740. The heat dissipation structure 790 may include a heat sink, a heat slug, or a thermal interface material (TIM) layer. For example, the heat dissipation structure 790 may include metal.

The upper package 20 may not include the upper substrate 710 and the conductive bumps 750. In this case, the memory semiconductor chip 720 may be disposed on the top surface of the second substrate 600, and memory chip pads 725 may be respectively connected to the connection terminals 675. The second molding layer 740 may be disposed on the top surface of the second substrate 600 and may cover the memory semiconductor chip 720.

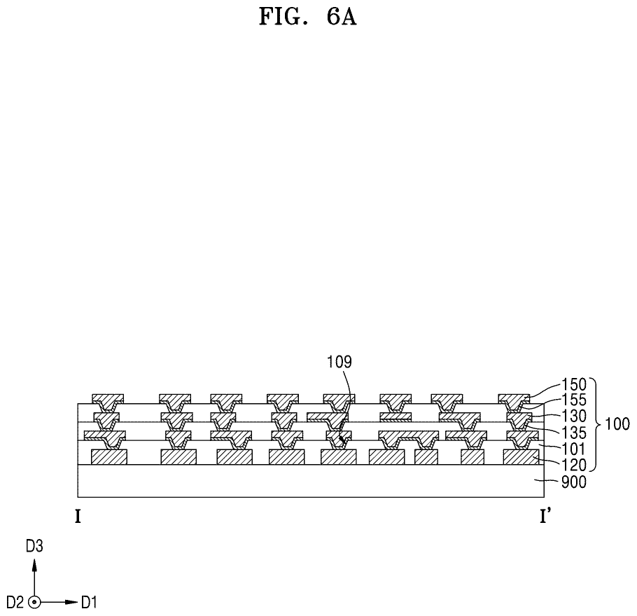

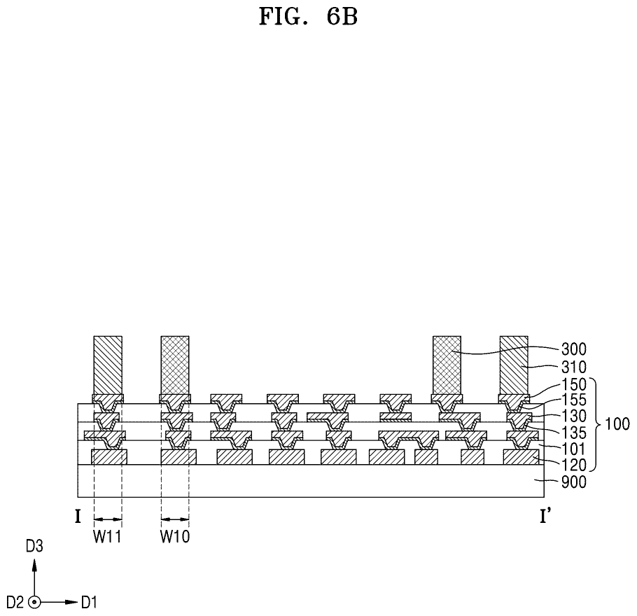

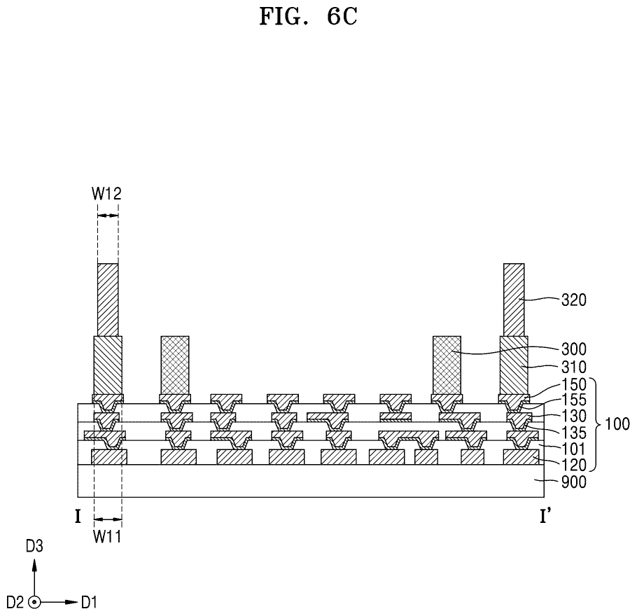

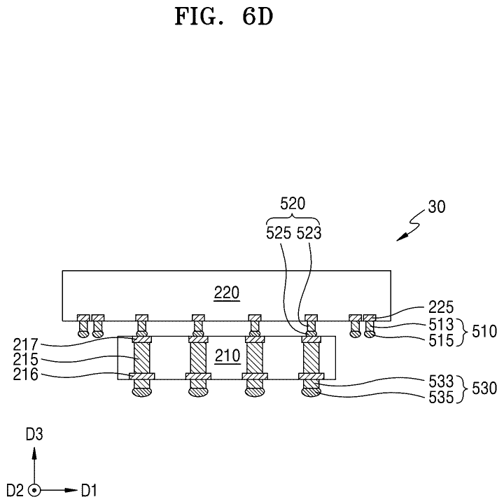

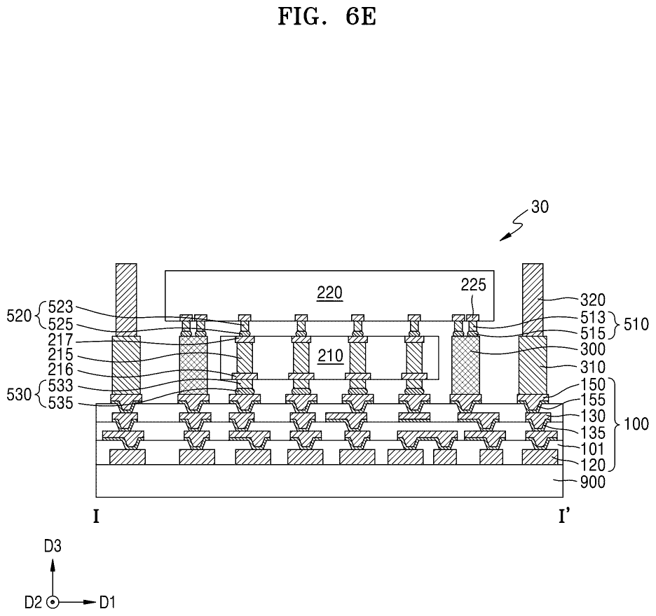

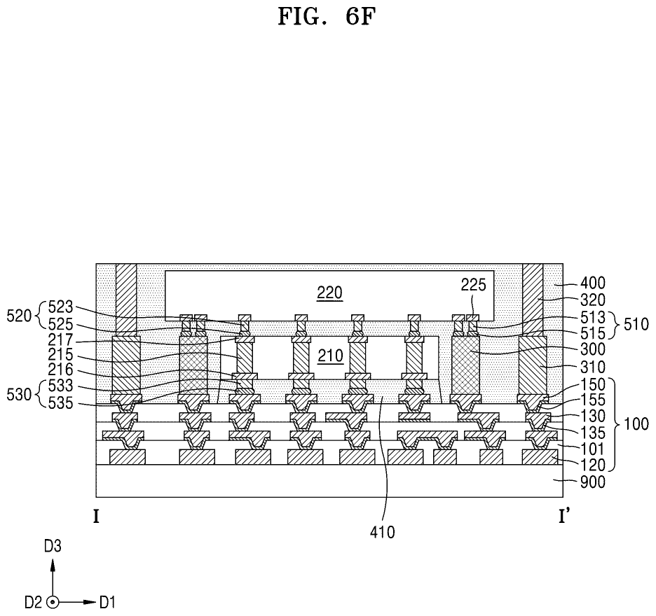

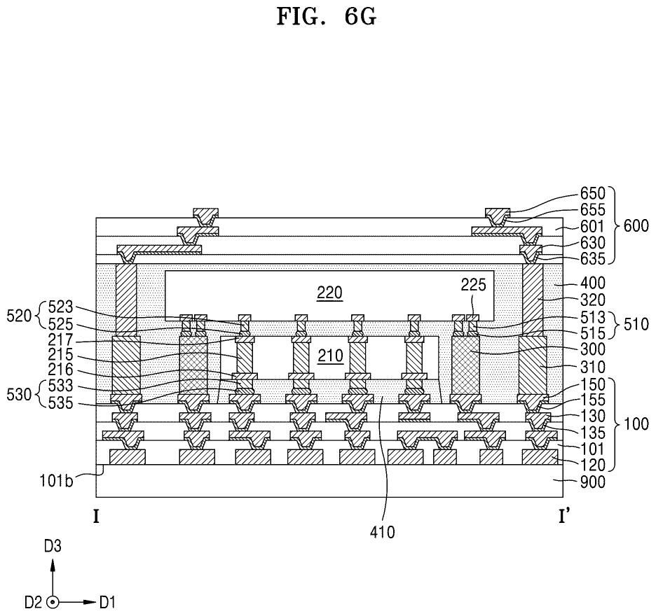

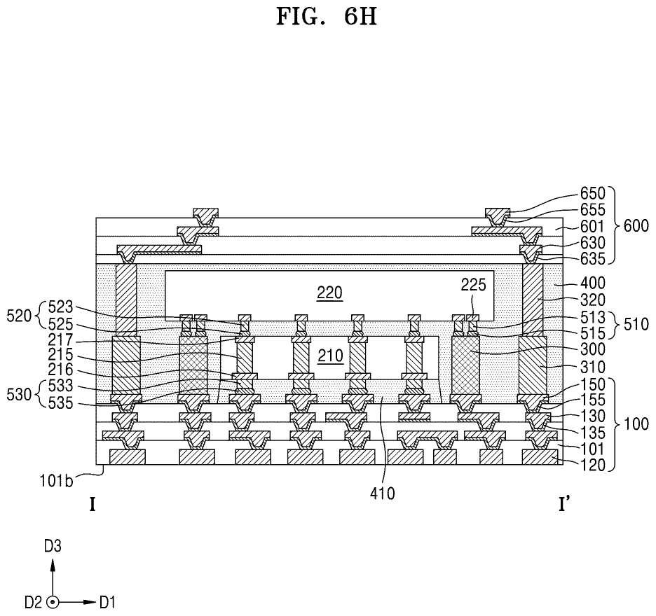

FIGS. 6A, 6B, 6C, 6D, 6E, 6F, 6G, and 6H are diagrams illustrating a method of manufacturing a semiconductor package according to embodiments and correspond to cross-sections taken along line I-I′ in FIG. 1A.

Referring to FIG. 6A, a plurality of under bump patterns 120, a first insulating layer 101, a plurality of first seed patterns 135, and a plurality of first redistribution patterns 130 may be formed on a carrier substrate 900. According to embodiments, the under bump patterns 120 may be formed on the carrier substrate 900 by using an electroplating process. The first insulating layer 101 may be formed on the carrier substrate 900 and cover the sidewalls and top surfaces of the under bump patterns 120. First openings 109 may be formed in the first insulating layer 101 and expose the under bump patterns 120. The first seed patterns 135 may be formed in the first openings 109, respectively, and on the top surface of the first insulating layer 101. The first redistribution patterns 130 may be respectively formed on the first seed patterns 135 by performing an electroplating process using the first seed patterns 135 as electrodes.

The process of forming a first insulating layer 101, the process of forming first seed patterns 135, and the process of forming first redistribution patterns 130 may be repeated and a stack of first insulating layers 101 and a stack of first redistribution patterns 130 may be formed. For example, the process of forming a first insulating layer 101, the process of forming first seed patterns 135, and the process of forming first redistribution patterns 130 may be repeatedly carried out one or more time. The first seed patterns 135 may be respectively formed on the bottom surfaces of the first redistribution patterns 130.

First redistribution pads 150 may be formed in and on the topmost first insulating layer 101 such that each of the first redistribution pads 150 is connected to a first redistribution pattern of the first redistribution patterns 130. Before the first redistribution pads 150 are formed, first seed pads 155 may be formed. The first redistribution pads 150 may be formed by performing an electroplating process using the first seed pads 155 as electrodes.

A first substrate 100 may be provided as a substrate for further elements or layers, for example, as described with reference to FIGS. 6B, 6C, 6D, 6E, 6F, 6G, and 6H. The first substrate 100 may include the first insulating layers 101, the under bump patterns 120, the first seed patterns 135, the first redistribution patterns 130, the first seed pads 155, and the first redistribution pads 150.

Referring to FIG. 6B, conductive posts 300 and lower interconnection structures 310 may be respectively formed on some of the first redistribution pads 150. For example, the conductive posts 300 and the lower interconnection structures 310 may be formed by performing an electroplating process on the first redistribution pads 150. The conductive posts 300 and the lower interconnection structures 310 may be formed together by a single electroplating process but the inventive concept is not limited thereto. The manufacture of the conductive posts 300 and the lower interconnection structures 310 may be simplified when the conductive posts 300 and the lower interconnection structures 310 are formed together by a single electroplating process. The conductive posts 300 and the lower interconnection structures 310 are formed together by a single electroplating process and the conductive posts 300 may include the same material as the lower interconnection structures 310. In a case where the conductive posts 300 and the lower interconnection structures 310 are formed by separate electroplating processes, the conductive posts 300 may include a different material than the lower interconnection structures 310. The height of each of the conductive posts 300 may be about 95% to about 105% of the height of each of the lower interconnection structures 310. The width W10 of the conductive posts 300 may be the same as, or different from the width W11 of the lower interconnection structures 310.

Referring to FIG. 6C, upper interconnection structures 320 may be respectively formed on the lower interconnection structures 310. According to embodiments, the upper interconnection structures 320 may be formed by performing an electroplating process using the lower interconnection structures 310 as electrodes. The upper interconnection structures 320 may include the same metal material as the lower interconnection structures 310. The width W12 of the upper interconnection structures 320 may be less than the width W11 of the lower interconnection structures 310. In a case where the width W12 of the upper interconnection structures 320 may be less than the width W11 of the lower interconnection structures 310, the upper interconnection structures 320 may be appropriately and respectively formed on the top surfaces of the lower interconnection structures 310. Upper interconnection structures 320 may be omitted and not be formed on the conductive posts 300.

Referring to FIG. 6D, a chip stack 30 may be prepared. The chip stack 30 may include a lower semiconductor chip 210 and an upper semiconductor chip 220. The chip stack 30 may further include lower bumps 530, first bumps 510, and second bumps 520. The lower bumps 530 may be disposed on the bottom surface of the lower semiconductor chip 210 and respectively connected to lower pads 216 of the lower semiconductor chip 210. The first bumps 510 may be disposed on the bottom surface of the upper semiconductor chip 220 and spaced apart from the lower semiconductor chip 210. For example, the first bumps 510 may not overlap the lower semiconductor chip 210 in the third direction D3. The second bumps 520 may be disposed between the lower semiconductor chip 210 and the upper semiconductor chip 220. For example, the second bumps 520 may overlap the lower semiconductor chip 210 and the upper semiconductor chip 220 in the third direction D3. The chip stack 30 may further include the second underfill film 420 described herein with reference to FIG. 3.

Referring to FIG. 6E, the chip stack 30 may be disposed on the top surface of the first substrate 100. The lower bumps 530 may be respectively connected to corresponding ones of the first redistribution pads 150. The lower bumps 530 may electrically connect the lower semiconductor chip 210 to the first substrate 100. For example, the lower bumps 530 may be connected to the first redistribution pads 150 by using a reflow process. Accordingly, the lower semiconductor chip 210 may be mounted on the first substrate 100.

The first bumps 510 may be connected to the conductive posts 300 such that the upper semiconductor chip 220 may be electrically connected to the first substrate 100 through the conductive posts 300. For example, the first bumps 510 may be connected to the conductive posts 300 by using a reflow process. The reflow process for the lower bumps 530 and the reflow process for the first bumps 510 may be simultaneously performed. For example, the reflow process for the lower bumps 530 and the reflow process for the first bumps 510 may be a same process and the manufacture of a semiconductor package may be simplified.

As described herein, the first bumps 510 and the second bumps 520 may be flipped relative to the example illustrated in FIGS. 1B and 6E.

Referring to FIG. 6F, a first molding layer 400 may be formed. The first molding layer 400 may be formed on the top surface of the first substrate 100 to cover the lower semiconductor chip 210, the upper semiconductor chip 220, the sidewalls of the conductive posts 300, the sidewalls of the lower interconnection structures 310, and the sidewalls of the upper interconnection structures 320. The first molding layer 400 may further cover the sidewalls of the first bumps 510. The first molding layer 400 may further extend to the second gap between the lower semiconductor chip 210 and the upper semiconductor chip 220 but the inventive concept is not limited thereto. The first molding layer 400 may expose the top surfaces of the upper interconnection structures 320.

Before the first molding layer 400 is formed, a first underfill film 410 may be formed in the lower gap between the first substrate 100 and the lower semiconductor chip 210. Alternatively, the first underfill film 410 may be omitted and the first molding layer 400 may extend to the lower gap between the first substrate 100 and the lower semiconductor chip 210. For example, the first molding layer 400 may fill the lower gap between the first substrate 100 and the lower semiconductor chip 210.

Referring to FIG. 6G, a second substrate 600 may be manufactured by forming a second insulating layer 601, a plurality of second seed patterns 635, a plurality of second redistribution patterns 630, a plurality of second seed pads 655, and a plurality of second redistribution pads 650 on the first molding layer 400 and the upper interconnection structures 320. The second insulating layer 601 may include a plurality of stacked second insulating layers. The second insulating layers 601, the second seed patterns 635, the second redistribution patterns 630, the second seed pads 655, and the second redistribution pads 650 may be formed in substantially the same manner as the first insulating layers 101, the first seed patterns 135, the first redistribution patterns 130, the first seed pads 155, and the first redistribution pads 150 described in connection with FIG. 6A. The second redistribution pads 650 may be respectively and electrically connected to the upper interconnection structures 320 through the second redistribution patterns 630.

Referring to FIG. 6H, the carrier substrate 900 may be removed. Removal of the carrier substrate 900 may expose the bottom surface of the first substrate 100. For example, the bottom surface 101b of the bottommost first insulating layer 101 and the bottom surfaces of the under bump patterns 120 may be exposed. The process of forming the first substrate 100, the electroplating process for forming the conductive posts 300 and the lower interconnection structures 310, the electroplating process for forming the upper interconnection structures 320, the process of forming the first molding layer 400, and the process of forming the second substrate 600, which have been described herein with reference to FIGS. 6A, 6B, 6C, 6D, 6E, 6F, 6G, and 6H, may be performed at a wafer level.

Referring again to FIG. 1B, the passive device 800 may be mounted on the bottom surface of the first substrate 100. For example, solder connectors 875 may be respectively formed between a first conductive terminal 810 and an under bump patterns 120, and between the second conductive terminal 820 and the under bump patterns 120. The under bump patterns 120 corresponding to the first conductive terminal 810 and the second conductive terminal 820 may respectively correspond to the solder connectors 875 such that the passive device 800 may be electrically connected to the first substrate 100.

Solder ball terminals 175 may be respectively formed on the bottom surfaces of the other under bump patterns 120. The solder ball terminals 175 may be respectively connected to the other under bump patterns 120. The semiconductor package 10 may be manufactured according to embodiments described herein.

According to the inventive concept, a plurality of first bumps may be provided between an upper semiconductor chip and a conductive post. The first bumps may transmit a voltage between the conductive post and the upper semiconductor chip, and accordingly, the voltage may be stably transmitted to the upper semiconductor chip. Each of the first bumps may include a first solder pattern and a first pillar pattern. The first solder pattern may buffer a stress applied to the upper semiconductor chip. The upper semiconductor chip may emit heat, and where the upper semiconductor chip is disposed above a lower semiconductor chip, the heat may be effectively dissipated. In the case where the upper semiconductor chip is disposed above a lower semiconductor chip, the heat dissipation characteristic of the upper semiconductor chip may be improved.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first substrate;
a lower semiconductor chip on the first substrate;
a conductive post disposed on the first substrate, and including at least a portion laterally spaced apart from the lower semiconductor chip;
an upper semiconductor chip on the lower semiconductor chip and the conductive post; and
a plurality of first bumps disposed between the conductive post and the upper semiconductor chip,
wherein each of the plurality of first bumps includes:
a first pillar pattern; and
a first solder pattern disposed on the first pillar pattern.

2. The semiconductor package of claim 1, wherein the first solder pattern is disposed between the first pillar pattern and the conductive posts, and
the conductive post is configured to supply a voltage to the upper semiconductor chip through the plurality of first bumps.

3. The semiconductor package of claim 2, wherein
the plurality of first bumps include a dummy bump and a voltage supply bump, and
the dummy bump is electrically isolated from integrated circuits of the upper semiconductor chip.

4. The semiconductor package of claim 1, further comprising
a plurality of lower bumps disposed between the first substrate and the lower semiconductor chip,
wherein a width of the plurality of first bumps is less than a width of the lower bumps.

5. The semiconductor package of claim 1, further comprising
a plurality of second bumps disposed between the lower semiconductor chip and the upper semiconductor chip,
wherein each of the second bumps includes:
a second pillar pattern; and
a second solder pattern disposed on the second pillar pattern.

6. The semiconductor package of claim 5, wherein the second pillar pattern is connected to a chip pad of the upper semiconductor chip,
the second solder pattern is disposed between the second pillar pattern and the lower semiconductor chip, and
a width of the plurality of first bumps is about 90% to about 110% of a width of the second bumps.

7. The semiconductor package of claim 5, wherein
the second pillar pattern and the first pillar pattern are formed of a first material, and
the second solder pattern and the first solder pattern are formed of a second material.

8. The semiconductor package of claim 1, further comprising:
a lower interconnection structure disposed on a top surface of an edge region of the first substrate;
an upper interconnection structure disposed on the lower interconnection structure; and
a second substrate disposed on the upper interconnection structure and the upper semiconductor chip, and connected to the upper interconnection structure.

9. The semiconductor package of claim 8, wherein a height of the conductive post is about 95% to about 105% of a height of the lower interconnection structure.

10. The semiconductor package of claim 1, further comprising
a molding layer disposed on the first substrate, and covering the lower semiconductor chip and the upper semiconductor chip,
wherein the molding layer extends between the conductive post and the upper semiconductor chip and covers sidewalls of the plurality of first bumps.

11. A semiconductor package comprising:
a redistribution substrate;
a first lower semiconductor chip disposed on a top surface of the redistribution substrate;
a plurality of conductive posts disposed on the top surface of the redistribution substrate, and including at least a portion laterally spaced apart from the first lower semiconductor chip;
an upper semiconductor chip disposed on the first lower semiconductor chip and the plurality of conductive posts; and
a plurality of solder patterns disposed between a first conductive post of the conductive posts and the upper semiconductor chip,
wherein the plurality of solder patterns include a different metal material than the conductive posts, and
the first conductive post is configured to supply a voltage to the upper semiconductor chip.

12. The semiconductor package of claim 11, further comprising
a plurality of pillar patterns disposed on plurality of solder patterns and electrically connected to the upper semiconductor chip,
wherein the plurality of solder patterns include a different metal material than the plurality of pillar patterns.

13. The semiconductor package of claim 11, further comprising
a second lower semiconductor chip laterally spaced apart from the first lower semiconductor chip and the conductive posts, and
wherein the upper semiconductor chip is disposed on the second lower semiconductor chip.

14. The semiconductor package of claim 11, further comprising:
a lower interconnection structure disposed on the top surface of the redistribution substrate, and laterally spaced apart from the first lower semiconductor chip and the conductive posts; and
an upper interconnection structure on the lower interconnection structure,
wherein a width of the upper interconnection structure is less than a width of the lower interconnection structure.

15. The semiconductor package of claim 11, further comprising
a passive device on a bottom surface of the redistribution substrate,
wherein the passive device is electrically connected to the first conductive post through the redistribution substrate, and
the passive device vertically overlaps the first conductive post.

16. A semiconductor package comprising:
a first redistribution substrate including a first insulating layer, a first seed pattern, and a first redistribution pattern disposed on the first seed pattern, the first insulating layer including a photo-imageable polymer;
a solder ball terminal on a bottom surface of the first redistribution substrate;
a lower semiconductor chip mounted on a top surface of the first redistribution substrate, the lower semiconductor chip including a lower pad, a through via, and an upper pad;
a plurality of conductive posts disposed on the top surface of the first redistribution substrate, and laterally spaced apart from the lower semiconductor chip;
an upper semiconductor chip disposed on and connected to the lower semiconductor chip and the conductive posts;
a plurality of first bumps disposed between each conductive post of the conductive posts and the upper semiconductor chip, and connected to the conductive posts and the upper semiconductor chip;
a plurality of second bumps disposed between the lower semiconductor chip and the upper semiconductor chip;
a plurality of lower interconnection structures disposed on the top surface of the first redistribution substrate, and laterally spaced apart from the lower semiconductor chip, the upper semiconductor chip, and the conductive posts;
a plurality of upper interconnection structures respectively disposed on the lower interconnection structures;
a molding layer disposed on the top surface of the first redistribution substrate, and covering the lower semiconductor chip, sidewalls of the conductive posts, the upper semiconductor chip, sidewalls of the lower interconnection structures, and sidewalls of the upper interconnection structures; and
a second redistribution substrate disposed on the molding layer and the upper interconnection structures, and connected to the upper interconnection structures,
wherein each of the first bumps comprises:
a first pillar pattern and
a first solder pattern disposed between the first pillar pattern and the conductive posts,
each of the second bumps comprises
a second pillar pattern and
a second solder pattern disposed between the second pillar pattern and the lower semiconductor chip, and
the conductive posts are configured to supply a voltage to the upper semiconductor chip.

17. The semiconductor package of claim 16, further comprising
a plurality of lower bumps disposed between the first redistribution substrate and the lower semiconductor chip,
wherein a width of the lower bumps is greater than a first width of the first bumps, and
the width of the lower bumps is greater than a second width of the second bumps.

18. The semiconductor package of claim 17, wherein
each of the lower bumps comprises:
a lower pillar pattern connected to the lower pad; and
a lower solder pattern disposed between the lower pillar pattern and the first redistribution substrate.

19. The semiconductor package of claim 16, wherein
a width of the first pillar pattern is about 90% to about 110% of a width of the second pillar pattern,
the width of the first pillar pattern is about 1 μm to about 70 μm, and
a width of the conductive posts is about 5 μm to about 400 μm.

20. The semiconductor package of claim 16, wherein
the first solder pattern includes a material that is different from a material of the first pillar pattern and materials of the conductive posts, and
the first solder pattern and the second solder pattern are formed of a same material.
